(19) United States
(12) Patent Application Publication
(10) Pub. No.: US 2010/0169727 A1
(43) Pub. Date: Jul. 1, 2010

(54) EDA TOOL, SEMICONDUCTOR DEVICE, AND SCAN CHAIN CONFIGURATION METHOD

(75) Inventors: Daisuke ITO, Hamura (JP); Hiroki Yamanaka, Kunitachi (JP); Koki Tsutsumida, Ome (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/647,475

(22) Filed: Dec. 26, 2009

(30) Foreign Application Priority Data
Dec. 26, 2008 (JP) 2008-333335

(51) Int. Cl. G01R 31/3177; G06F 11/25

(52) U.S. Cl. 714/726; 714/E11.155

(57) ABSTRACT

There is provided a technique for avoiding test-time IR drops which occur when the frequency that adjacent FFs in a scan chain have different logical values increases. An expected value derivation module derives the expected value of each FF by calculating probability propagation or performing logic simulation. A grouping module groups each FF subject to a test into a number of groups by referring to the obtained expected value. A scan chain configuration module pairs two groups whose logical-value-1 intake frequencies are opposite to each other, performs logic reversal on one group, and configures one scan chain.

### CROSS-REFERENCE TO RELATED APPLICATIONS

The disclosure of Japanese Patent Application No. 2008-333335 filed on Dec. 26, 2008 including the specification, drawings and abstract is incorporated herein by reference in its entirety.

### BACKGROUND OF THE INVENTION

The present invention relates to a test facilitating design method of an EDA tool which is a design tool for a semiconductor device, and in particular, relates to the configuration of scan chains.

Test methods for semiconductor integrated circuits include a method called a scan test method. The scan test method is comprised of FFs for a scan test, scan chains formed by coupling FFs in series, and a combinational circuit subject to a test. The input terminals and output terminals of FFs can switch between normal-operation data and test data by selectors. A scan chain is formed by the coupling of test data input/output terminals. The combinational circuit subject to the test is disposed between scan chains, and coupled to the normal-operation data input/output terminals of FFs. When a test pattern contained in a tester is applied to scan FFs through external terminals, a selector changeover signal is set for test data, and as many clock signals as the number of FFs are inputted. This is called scan-in. During the test of the combinational circuit, the input/output terminals of FFs are set for normal-operation data. In this way, the test pattern applied to FFs passes through the combinational circuit and is taken in FFs again as a response pattern. The response pattern is taken out to the tester through external terminals by switching selectors as in the scan-in. This is called scan-out. The comparison of the taken response pattern with a normal-operation response pattern enables the test of the combinational circuit.

At the present day, due to advanced fine-line structures, there is a problem of an IR drop as well as crosstalk during the scan test. The IR drop refers to that voltage supplied to FFs etc. drops or delays due to interconnection resistance.

For the IR drop during the scan test, the frequency that adjacent FFs in the scan chain have different values is important. The frequency that adjacent flip-flops in the scan chain have different values is defined as follows. With the FFs sequenced in the scan chain, the logical value of the ith FF is represented by αᵢ. The count that the ith FF and the (i+1)th FF have different values is represented by |αᵢ−αᵢ₊₁|. By summing the counts for all i's, the count Σᵢ|αᵢ−αᵢ₊₁| that the adjacent FFs in the scan chain have different logical values can be obtained. The logical values of the FFs differ among different test patterns; therefore, by summing the counts for all test patterns, Σ_{test pattern}Σ|αᵢαᵢ₊₁| is obtained. The frequency that the adjacent FFs have different logical values is represented as {1/N×(M−1)}×Σ_{test pattern}Σᵢ|αᵢ−αᵢ₊₁|, where N is the number of test patterns, and M is the number of FFs configuring the scan chain. As the frequency that the adjacent FFs have different logical values increases, an area where logical values change simultaneously in a semiconductor integrated circuit increases, so that the risk of IR drops increases. Therefore, by minimizing the frequency that the adjacent FFs have different logical values, it is possible to reduce IR drops.

The following patent documents as examples describe methods for reducing IR drops during the scan test.

Japanese Unexamined Patent Publication No. Hei 11 (1999)-304889 (patent document 1) discloses a test pattern generation method. FIG. 1 of the patent document 1 shows a flow for generating a test pattern for suppressing the number of simultaneous output changes in a semiconductor integrated circuit by deleting a specific test pattern among test patterns comprised of logic “0s” and logic “1s” or changing the execution sequence.

Japanese Unexamined Patent Publication No. 2006-066825 (patent document 2) discloses a method for preventing malfunctions caused by IR drops during a scan test for a semiconductor integrated circuit. FIG. 1 of the patent document 2 shows a method for performing IR drop analysis using operation factor information and repeating the grouping of scan circuits until the result becomes OK.

### SUMMARY OF THE INVENTION

However, in the patent document 1, although a test pattern for reducing the frequency that adjacent FFs in a scan chain have different logical values is selected, values obtained after FFs receive a response pattern cannot be controlled. As a result, during scan-out, the frequency that the adjacent FFs have different logical values increases, so that IR drops cannot be reduced.

In the patent document 2, IR drop analysis is performed with operation factor information, and scan circuits are grouped. The purpose of this is to reduce IR drops that occur when all semiconductor integrated circuits operate simultaneously by shifting the operation timings of the grouped scan circuits. Therefore, in the patent document 2, attention is not focused on the frequency that the adjacent FFs have different logical values, and it cannot be denied that an actual scan test time may increase compared to when the semiconductor integrated circuits operate simultaneously.

It is an object of the present invention to provide a technique for suppressing test-time IR drops which occur when the frequency that adjacent FFs in a scan chain have different logical values increases during a scan test.

The above and other objects and novel features of the present invention will become apparent from the description of this specification and the accompanying drawings.

A typical aspect of the invention disclosed in the present application will be briefly described as follows.

An EDA tool according to a typical aspect of the invention includes an expected value derivation module for deriving an expected value of each flip-flop of a semiconductor device subject to verification; a grouping module for grouping each flip-flop into a plurality of groups, based on the expected value of each flip-flop of the semiconductor device subject to verification; and a scan chain configuration module for configuring a scan chain of each group; the EDA tool being able to call the expected value derivation module, the grouping module, and the scan chain configuration module.

Another EDA tool according to a typical aspect of the invention includes an expected value derivation module for deriving an expected value of each flip-flop of a semiconductor device to be verified by the EDA tool; a grouping module for grouping each flip-flop into a plurality of groups, based on the expected value of each flip-flop of the semiconductor device subject to verification; and a scan chain configuration module for pairing two groups among the groups, reversing polarity of each flip-flop belonging to one group of the pair, and configuring a scan chain of each pair; the EDA tool being able to call the expected value derivation module, the grouping module, and the scan chain configuration module.

In the EDA tool, the expected value derivation module may derive, by calculating probability propagation, the expected value of each flip-flop of the semiconductor device subject to verification.

In the EDA tool, the expected value derivation module may derive, by performing logic simulation, the expected value of each flip-flop of the semiconductor device subject to verification.

In the EDA tool, the grouping module may read a step width of each group which is used as a basis for determination at the time of grouping, and determine which group the expected value of each flip-flop of the semiconductor device subject to verification belongs to.

A semiconductor device according to a typical aspect of the invention includes a plurality of scan chains including a first scan chain and a second scan chain, wherein an expected value that each flip-flop belonging to the first scan chain takes a logical value “1” falls within a first step width, an expected value that each flip-flop belonging to the second scan chain takes the logical value “1” falls within a second step width, and the first step width and the second step width differ from each other.

In the semiconductor device, the expected value that each flip-flop belonging to the first scan chain takes the logical value “1” and the expected value that each flip-flop belonging to the second scan chain takes the logical value “1” are obtained by probability propagation.

A scan chain configuration method by an EDA tool according to a typical aspect of the invention which can call an expected value derivation module, a grouping module, and a scan chain configuration module includes an expected value derivation step of deriving, by the expected value derivation module, an expected value of each flip-flop of a semiconductor device subject to verification; a step width readout step of reading, by the grouping module, a step width of a group; a grouping step of determining, by the grouping module, which group corresponding to the step width each flip-flop of the semiconductor device subject to verification belongs to; and a scan chain configuration step of configuring, by the scan chain configuration module, a scan chain with flip-flops in a group assigned in the grouping step.

Another scan chain configuration method by an EDA tool according to a typical aspect of the invention which can call an expected value derivation module, a grouping module, and a scan chain configuration module includes an expected value derivation step of deriving, by the expected value derivation module, an expected value of each flip-flop of a semiconductor device subject to verification; a step width readout step of reading, by the grouping module, a step width of a group; a grouping step of determining, by the grouping module, which group corresponding to the step width each flip-flop of the semiconductor device subject to verification belongs to; a pair configuration step of pairing two groups among groups formed in the grouping step; a polarity reversal step of reversing, by the scan chain configuration module, polarity of each flip-flop of one group included in a pair formed in the pair configuration step; and a scan chain configuration step of configuring a scan chain of each pair by unifying the one group in which the polarity of each flip-flop is reversed in the polarity reversal step and the other group in which polarity of each flip-flop is not reversed.

A typical effect of the invention disclosed in the present application will be briefly described as follows.

With a scan chain configuration method according to the typical aspect of the invention, it is possible to reduce IR drops during a scan test. As a result, it is possible to reduce the time and man-hour required for the scan test.

### BRIEF DESCRIPTION OF THE DRAWINGS

FIG. 1 is an example of a test circuit and a semiconductor device subject to a scan test with a test pattern according to the present invention.

FIG. 2 is an explanatory diagram showing an operation example of the invention, using a simple combinational circuit.

FIG. 3 is another explanatory diagram showing an operation example of the invention, using a simple combinational circuit.

FIG. 4 is a configuration diagram of an EDA tool according to the invention.

FIG. 5 is a flowchart showing a procedure for expected value derivation according to a first embodiment of the invention.

FIG. 6 is a flowchart showing a procedure for grouping according to the invention.

FIG. 7 is a flowchart showing a procedure for scan chain configuration according to the invention.

FIG. 8 is a flowchart showing a procedure for expected value derivation according to a second embodiment of the invention.

FIG. 9 is a conceptual diagram showing a difference between operations during a scan test and a normal operation.

### DETAILED DESCRIPTION OF THE PREFERRED EMBODIMENTS

### First Embodiment

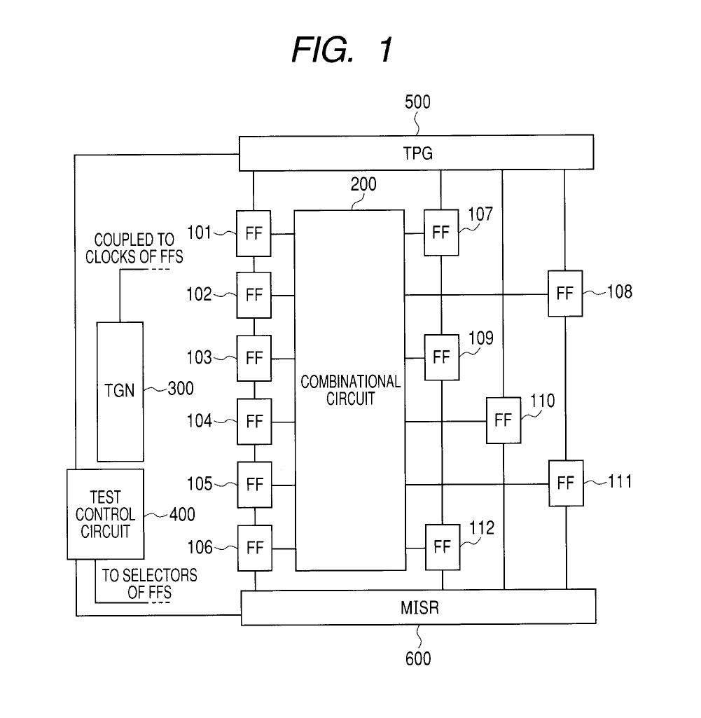

FIG. 1 is an example of a test circuit and a semiconductor device subject to a scan test with a test pattern according to the present invention.

The semiconductor device in FIG. 1 includes flip-flops (FFs) 101 to 112, a combinational circuit 200, a test clock generating circuit (TGN) 300, a test control circuit 400, a random-number pattern generating circuit (TPG) 500, and a compression circuit (MISR) 600.

The FFs 101 to 112 are flip-flop groups for enabling a scan test.

The combinational circuit 200 is a circuit comprised of a plurality of logic elements. The FFs 101 to 112 are coupled in series so that a test pattern can be applied to the FFs 101 to 112 through external terminals. The coupling of FFs is called a scan chain. In FIG. 1, the FFs 101 to 106 configure a scan chain, the three FFs 107, 109, and 112 configure another scan chain, the two FFs 108 and 111 configure another scan chain, and only the FF 110 configures the other scan chain.

The test clock generating circuit (TGN) 300 is a circuit for generating clock signals during the scan test.

The test control circuit 400 is a circuit for controlling a logic BIST (Build-In Self Test) circuit during the scan test.

The random-number pattern generating circuit (TPG) 500 is a circuit for generating random numbers for the scan test.

The compression circuit (MISR: Multi Input Signature Register) 600 is a circuit for compressing the test pattern for the scan test.

Next, a test method for the semiconductor device will be described.

The random numbers generated by the random-number pattern generating circuit (TPG) 500 are scanned in the FFs 101 to 112 through the scan chains. At this time, the test clock generating circuit (TGN) 300 supplies the clock signals of the FFs 101 to 112.

Logical values set to the FFs 101 to 112 pass through the combinational circuit 200 during the test.

Logical values obtained through the combinational circuit 200 are supplied to the compression circuit (MISR) 600 through the scan chains.

Conventionally, there are few cases where only one scan chain is assigned to one semiconductor device. This is because there are many cases where the confirmation of more complex operations by the combination of scan chains configured for individual functions can reduce the temporal cost in terms of fault isolation.

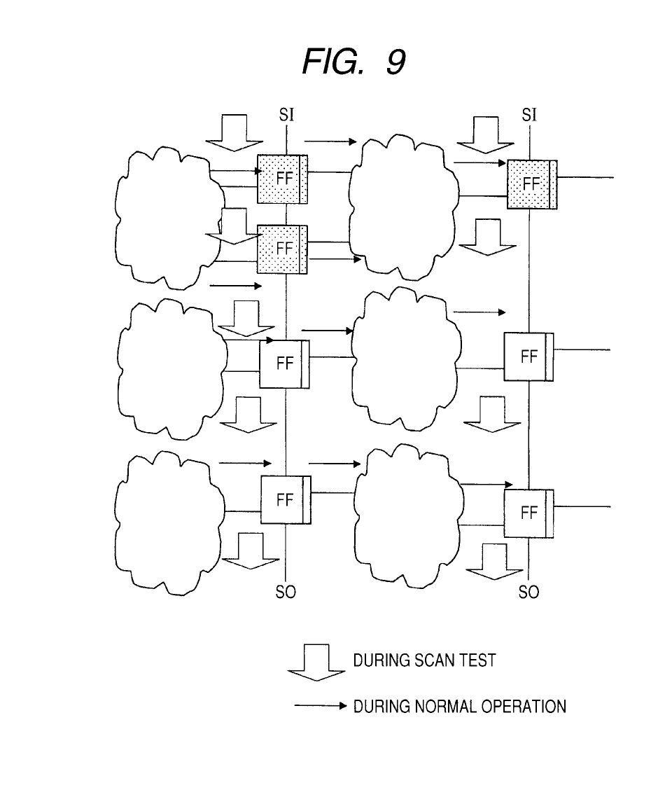

FIG. 9 is a conceptual diagram showing a difference between operations during a scan test and a normal operation. In most cases, as shown in FIG. 9, scan chains are configured, regardless of processing during the normal operation. In this configuration, only some functions of the semiconductor device are used during the normal operation; therefore, the probability of change of flip-flops in the whole semiconductor device is low. When three flip-flops (hatched to be distinguished) which are located at the top in FIG. 9 operate, the other flip-flops often do not operate. On the other hand, all the flip-flops operate during the scan test; therefore, the probability of change of flip-flops is high, which causes circuit malfunctions due to IR drops.

Thus, how to assign scan chains is a very important factor to facilitate the test for the semiconductor device.

Conventionally, there have been proposed various methods for configuring scan chains, including a method for providing scan chains for individual function operations as described above, a method for averaging the number of shift cycles of scan chains by substantially equalizing FFs configuring all scan chains, a method for suppressing an increase in chip area by minimizing the number of scan test patterns used only in scan tests, and a method of not providing scan chains within hardware that is considered “to have already matured (to have use accomplishments and few problems such as failures)”.

In the invention, at the time of configuring scan chains, an FF whose logical value is likely to become “1” and an FF whose logical value is unlikely to become “1” are assigned to different scan chains. Further, an FF whose logical value is likely to become “0” undergoes logic reversal, and is assigned to the same scan chain as the FF whose logical value is likely to become “1”. This makes it possible to suppress the probability of change of FFs during scan-out.

A more specific description will be made below.

### (1) Derivation of Expected Value

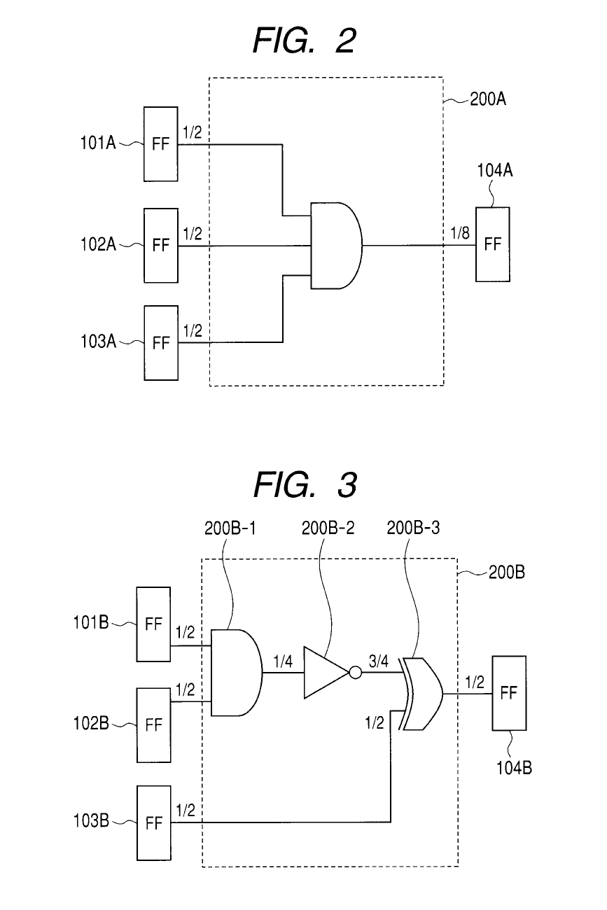

First, the deviation of the logical value of each FF is calculated by probability propagation among various methods. A specific method will be described with reference to FIG. 2.

FIG. 2 is an explanatory diagram showing an operation example of the invention, using a simple combinational circuit.

FIG. 3 is another explanatory diagram showing an operation example of the invention, using a simple combinational circuit.

First, FIG. 2 will be described.

In FIG. 2, FFs 101A, 102A, 103A, and 104A are provided to evaluate a combinational circuit 200A. The combinational circuit 200A is a simple three-input AND (logical product) circuit. For evaluation thereof, the FFs 101A, 102A, and 103A for input and the FF 104A for output are provided.

The FFs for input configure a scan chain from the outside. In association therewith, data is specified by data input from the outside to the FFs. In FIG. 2, assume that the probability that each FF for input becomes “1” is 50% for purposes of explanation.

On the other hand, the FF 104A for output depends on the combinational circuit 200A. That is, if the probability that “1” is inputted to each input terminal of the three-input AND (logical product) circuit is 50%, the expected value that the FF 104A becomes “1” is 12.5% (⅛).

Next, FIG. 3 will be described.

In FIG. 3, FFs 101B, 102B, 103B, and 104B are provided to evaluate a combinational circuit 200B.

The combinational circuit 200B of FIG. 3 includes a two-input AND (logical product) circuit 200B-1, an inverter 200B-2, and a two-input XOR (exclusive OR) circuit 200B-3. Refer to FIG. 3 for mutual coupling.

The FFs 101B and 102B for input are coupled to the two-input AND circuit 200B-1. Assuming that the probability that each of the FFs 101B and 102B becomes “1” is 50% as in FIG. 2, the probability that the two-input AND circuit 200B-1 becomes “1” is 25% (¼).

Since logic reversal thereof is performed by the inverter 200B-2, “1” is inputted to one of the input terminals of the two-input XOR circuit 200B-3 with a probability of 75% (¾).

The FF 103B for input is coupled to the other terminal of the two-input XOR circuit 200B-3. As described above, the expected value of each FF for input is 50% (½). Therefore, the expected value that the output of the two-input XOR circuit 200B-3 (the input of the FF 104B) becomes “1” is 50% (½).

In this way, the probability that “1” is inputted to the input of each FF is derived by probability propagation.

### (2) Grouping

Next, grouping is performed on FFs configuring scan chains, based on obtained expected values. This grouping is performed in accordance with the given width of probabilities, depending on the circuit size and configuration and the number of scan chains. The following is an example thereof.

Group 1: the probability of occurrence of the logical value “1” is less than 20%. Group 2: the probability of occurrence of the logical value “1” is between 20% and 40%. Group 3: the probability of occurrence of the logical value “1” is between 40% and 60%. Group 4: the probability of occurrence of the logical value “1” is between 60% and 80%. Group 5: the probability of occurrence of the logical value “1” is not less than 80%. In this way, the probabilities of occurrence of the logical value “1” are aligned for each scan chain. In this specification, the width of expected values assigned to each group is called “step width”. This makes it possible to align the probabilities of change of FFs belonging to each scan chain. For example, the change rate of FFs of each scan chain corresponding to the center value of each group will be shown as follows.

Group 1: 18%, Group 2: 42%, Group 3: 50%, Group 4: 42%, Group 5: 18%. Thus, by unifying FFs having similar change rates into the same scan chain, it is possible to reduce IR drops during the scan test, prevent malfunctions caused thereby, and reduce power consumption.

While the same width is assigned in steps of 20% as described above, the width may be varied among the groups. For example, Group 1: 25%, Group 2: 20%, Group 3: 10%, Group 4: 20%, Group 5: 25%.

### (3) Configuration of Scan Chain

After the completion of the grouping in (2), the scan chain of each group is arranged. At this time, if there exist groups whose logical-value-1 intake probabilities are opposite to each other, logic reversal is performed on one group, so that the logical-value-1 intake probabilities can be equivalent. In this case, the two groups can be unified into one scan chain. In the above example, in the group 1, the probability of occurrence of the logical value “1” is less than 20%. On the other hand, in the group 5, the probability of occurrence of the logical value “1” is not less than 80%. Accordingly, after logic reversal is performed on the FFs belonging to the group 5, the probability of occurrence of the logical value “1” is not more than 20% in the reversed group 5. Since this is approximately equal to that of the group 1, by unifying the group 1 and the reversed group 5 it is possible to reduce the number of scan chains.

On the other hand, from the viewpoint of preventing IR drops, the minimization of the interconnection lengths of scan chains is required. Thus, the configuration of scan chains in consideration of other conditions (e.g., scheduling) is required.

The processes described above are performed by a designer. More specifically, the designer performs these processes, using an EDA (Electric Design Automation) tool which operates on a PC (Personal Computer) or a WS (Work Station). Hereinafter, an execution environment for this work will be described.

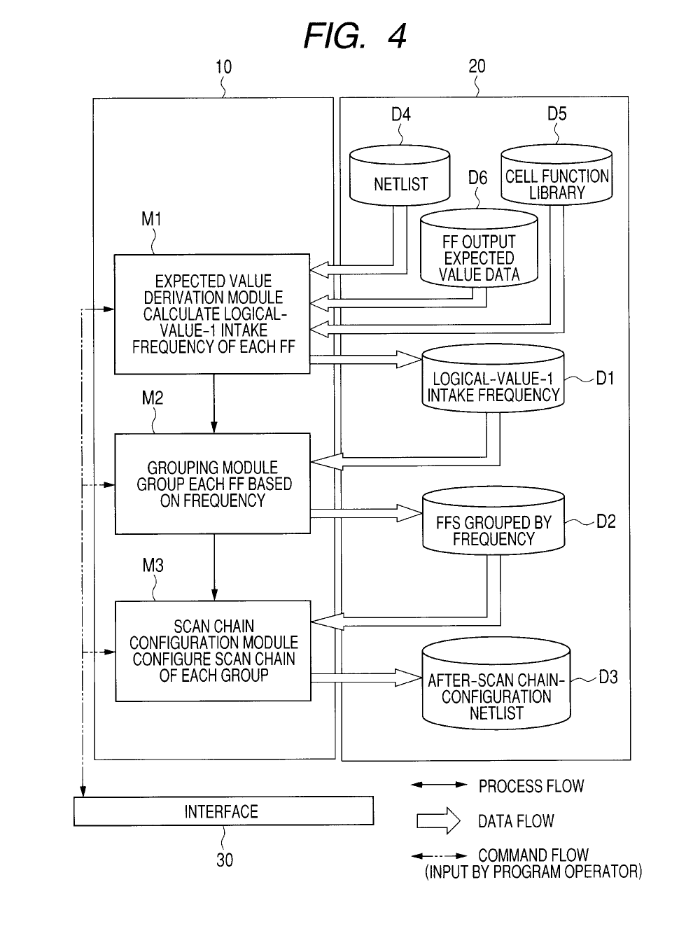

FIG. 4 is a configuration diagram of an EDA tool according to the invention.

The EDA tool operates on a PC. The PC includes an execution unit 10, a data storage unit 20, and an interface 30. The execution unit 10 includes not only a CPU (Central Processing Unit) for executing actual processing, but also a DRAM and the like.

The data storage unit 20 is a storage unit such as an HDD (Hard Disk Drive) containing programs and net lists used in processing by the execution unit 10 and a cell function-related library (cell function library).

The interface 30 is a generic name for input means and output means which interface with an operator of the PC. The input means include a keyboard, a mouse, and a touch panel, and the output means include a display.

The EDA tool has various functions; however, functions related to the invention will be described herein. It is needless to say that it has general functions (not described) of EDA tools. Further, an application designed specifically for scan chain configuration according to this embodiment can be used.

As described above, there are three processes related to the invention. First, expected value derivation which is the first process of the three processes is performed.

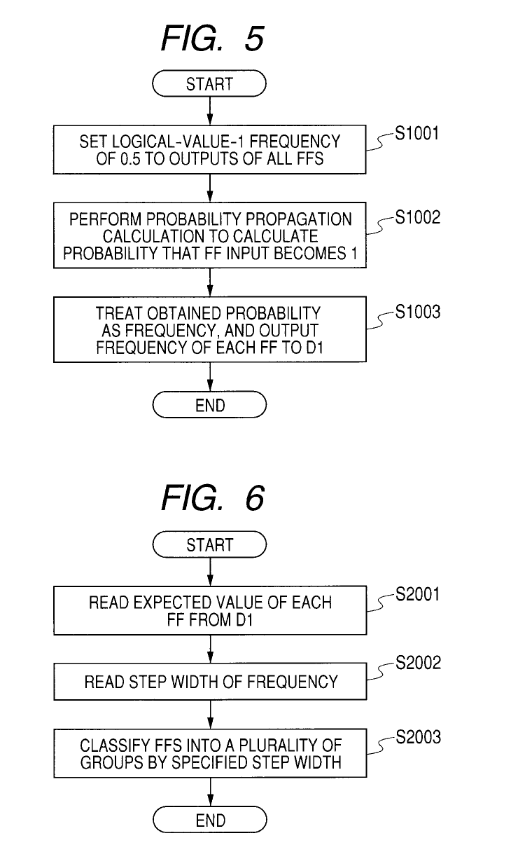

FIG. 5 is a flowchart showing a procedure for expected value derivation according to the first embodiment of the invention. Assume that the EDA tool body etc. which operate in the execution unit 10 have already read an expected value derivation module M1 from the data storage unit 20 and started the execution before the start of the process of FIG. 5. Further, assume that the circuit configuration regarding expected value derivation has been read from a netlist D4 and a cell function library D5.

First, the probability that each FF becomes the logical value “1” is set to 0.5 (½) (step S1001). The ways to input the data in step S1001 include the following.

(1) The value is specified as an initial value in a program of the expected value derivation module M1.

(2) The value is manually inputted through the interface 30.

(3) The value is read from a predetermined file stored in the data storage unit 20.

The input way is not limited thereto, and may be any other way by which a necessary value can be acquired.

Next, probability propagation calculation is performed so that the probability that the logical value to the input of each FF becomes “1” is calculated (step S1002). More specifically, it is calculated in the manner shown in FIGS. 2 and 3.

Lastly, the obtained probability is treated as the frequency of intake of the logical value “1”, and the expected value derivation module M1 stores the derived expected value as a logical-value-1 intake frequency into a predetermined storage area (D1 in FIG. 4) of the data storage unit 20 (step S1003).

After the completion of the process by the expected value derivation module M1, the flow proceeds to “(2) grouping” described above. At this time, a grouping module M2 performs this process. It is a matter of design whether the EDA tool body, the expected value derivation module M1, or another module activates the grouping module M2.

FIG. 6 is a flowchart showing a procedure for grouping according to the invention.

First, the grouping module M2 reads the expected value of each FF stored in the predetermined storage area D1 of the data storage unit 20 by the expected value derivation module M1 (step S2001). Further, the grouping module M2 reads the “step width” of the expected value which is used as the basis for grouping FFs as described in “(2) grouping” (step S2002).

The grouping module M2 confirms which group based on the “step width” read in step S2002 the expected value of each FF belongs to, and determines the group to which the FF belongs (step S2003). Although not shown in FIG. 4, the grouping module M2 reads the “step width” from the data storage unit 20. Alternatively, it may be inputted through the interface 30.

The grouping module M2 stores the result of the grouping in a predetermined storage area (D2 in FIG. 4), and ends the operation.

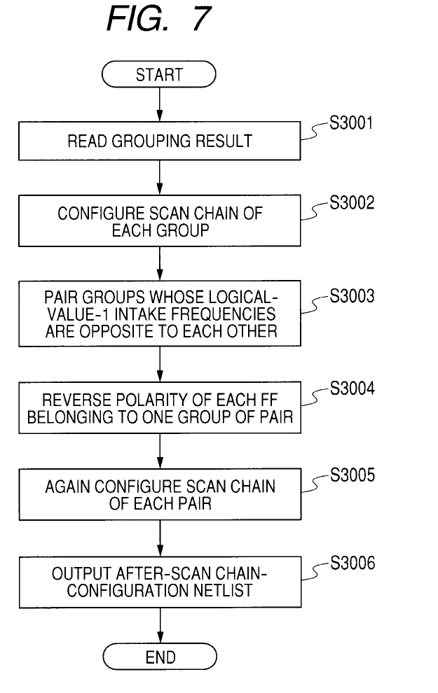

After the completion of the process by the grouping module M2, it is possible to start the process of “(3) configuration of scan chain”. The EDA tool body or the grouping module M2 activates a scan chain configuration module M3. The scan chain configuration module M3 reads the FF grouping stored in the predetermined storage area D2, and configures the scan chain of each group. FIG. 7 is a flowchart showing a procedure for scan chain configuration according to the invention.

First, the scan chain configuration module M3 reads the grouping result stored in the predetermined storage area D2 (step S3001). Based on the grouping result, the scan chain configuration module M3 configures the scan chain of each group (step S3002). Then, the scan chain configuration module M3 pairs groups whose logical-value-1 intake frequencies are opposite to each other (step S3003). A description thereof will be made below with reference to the example of “(2) grouping” described above.

In the group 1, the probability of taking the logical value “1” is less than 20%. In the group 2, the probability of taking the logical value “1” is between 20% and 40%. Accordingly, the group 1 is paired with the group 5 (the probability of occurrence of the logical value “1” is not less than 80%), and the group 2 is paired with the group 4 (the probability of occurrence of the logical value “1” is between 60% and 80%).

In the foregoing, the group 3 cannot be paired with any other group. In this case, the scan chain configuration module M3 does not have to configure a pair. If it is possible to refer to the logical-value-1 intake frequency of each FF (stored in the predetermined storage area D1), the group 3 may be divided into two parts including one part between 40% and 50% and the other part between 50% and 60%, thus to establish a pseudo-pair.

After configuring the pairs, the scan chain configuration module M3 reverses the polarity of one group of each pair (step S3004). For example, in the above example, the scan chain configuration module M3 reverses the polarity of only the group 1 in the pair of the groups 1 and 5.

Then, the scan chain configuration module M3 again configures the scan chain of each pair (step S3005). That is, the two scan chains including the group 1 of the reversed polarity and the group 5 of the non-reversed polarity are unified into one. This can reduce the five scan-chain groups to three.

Lastly, the scan chain configuration module M3 stores an after-scan chain-configuration netlist in a predetermined storage area (D3 in FIG. 4) (step S3006).

The EDA tool body determines the arrangement, coupling, and the like of FFs, using the after-scanchain-configuration netlist stored in the predetermined storage area D3.

Thus, by pairing groups whose logical-value-1 intake frequencies are opposite to each other, reversing the polarity of one group of each pair, and again configuring the scan chain of each pair, the EDA tool can reduce the number of scan chains in the semiconductor device.

Further, the frequency that adjacent FFs in each group and each pair have different logical values is reduced. Consequently, it is possible to avoid IR drops during the test.

The omission of above steps in accordance with design requirements is also included within the scope of the invention. For example, in the above description, the polarity is reversed in step S3004 and the two scan chains of groups are unified into one in step S3005 to reduce the number of scan chains. However, steps S3004 and 3005 may be omitted, and the scan chain of each group may be configured in step S3006.

In step S1001, the expected value that each FF takes the logical value “1” is set to 0.5. However, in the case of having multiple multistage combinational circuits 200, if the expected value of the output of the combinational circuit 200 in the preceding stage is known, a value other than 0.5 may be inputted.

Further, the above-described three modules may be unified into one software module. Alternatively, further segmented modules may be configured. Module configuration differences caused by software design technique such as conversion to functions, classes, and objects are certainly included within the scope of the invention.

### Second Embodiment

Next, the second embodiment of the invention will be described.

In the first embodiment, probability propagation is derived by calculation to obtain the frequency of intake of the logical value “1”. In the second embodiment, a method for obtaining the frequency by performing logic simulation will be explained. The configuration diagram of the EDA tool according to the invention is substantially the same as FIG. 4, and therefore is omitted herein. In this embodiment, the FF output expected value data D6 is not used.

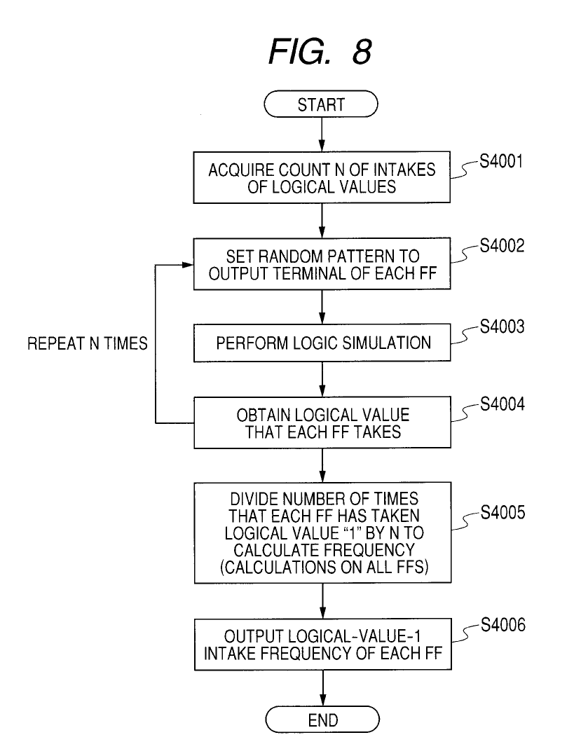

FIG. 8 is a flowchart showing a procedure for expected value derivation according to the second embodiment of the invention. This process is substituted for that of FIG. 5. Accordingly, assume that the EDA tool body which operates in the execution unit 10 has already read the expected value derivation module M1 from the data storage unit 20 and started the execution before the start of the process of FIG. 8. Further, assume that readout from the netlist D4 and the cell function library D5 has been completed as in FIG. 5.

First, the count N of intakes of logical values is acquired (step S4001). At this time, the intake count N may be specified by a program of the expected value derivation module M1 or by input through the interface 30, or may be read from a file. Specific setting is a matter of design.

Then, the expected value derivation module M1 sets a random pattern to the output terminal of each FF (step S4002). The “random pattern” refers to a pattern formed by randomly selecting the logical value “0” or “1”. After setting the random pattern, the expected value derivation module M1 performs logic simulation (step S4003). By the logic simulation, the random pattern set in step S4002 passes through the combinational circuit 200 disposed between the FF output terminal and the next-stage FF input terminal. A logical value obtained through the combinational circuit 200 is set to the next-stage FF input terminal.

Then, the expected value derivation module M1 obtains the logical value that each FF takes (step S4004). “The logical value that the FF takes” refers to the logical value that is set to the input terminal of the FF after the logic simulation.

The series of steps are repeated N times acquired in step S4001.

After repeating the steps N times, the expected value derivation module M1 divides the number of times that each FF has taken the logical value “1” by the repeat count N. In this way, the expected value derivation module M1 obtains the frequency that each FF takes the logical value “1” (step S4005). For example, consideration will be given to a case where N=100 and the number of times that one FF has taken the logical value “1” is 32. In this case, the frequency that the FF takes the logical value “1” is 32/100=0.32.

Thus, the expected value derivation module M1 obtains the logical-value-1 intake frequencies of all FFs. Then, the expected value derivation module M1 stores the obtained probabilities in the predetermined storage area D1 of the data storage unit 20 (step S4006).

Thus, by performing the logic simulation to obtain the logical-value-1 intake frequency of each FF which is set as the theoretical value of the intake frequency that the logical value “1” is inputted to the next-stage FF input terminal, it is possible to obtain the frequency of intake of the logical value “1” in a state close to an actual operating environment.

While the invention made above by the present inventors has been described specifically based on the illustrated embodiments, the present invention is not limited thereto. It is needless to say that various changes and modifications can be made thereto without departing from the spirit and scope of the invention.

The invention has been described on the assumption of implementation as one of the modules in the EDA tool. However, the invention is not necessarily limited thereto. The implementation of independent software for creating the netlist of optimal scan chains is also included within the scope of the invention.

1. An EDA tool comprising:
an expected value derivation module for deriving an expected value of each flip-flop of a semiconductor device subject to verification;
a grouping module for grouping each flip-flop into a plurality of groups, based on the expected value of each flip-flop of the semiconductor device subject to verification; and
a scan chain configuration module for configuring a scan chain of each group,
the EDA tool being able to call the expected value derivation module, the grouping module, and the scan chain configuration module.

2. An EDA tool comprising:
an expected value derivation module for deriving an expected value of each flip-flop of a semiconductor device to be verified by the EDA tool;
a grouping module for grouping each flip-flop into a plurality of groups, based on the expected value of each flip-flop of the semiconductor device subject to verification; and
a scan chain configuration module for pairing two groups among the groups, reversing polarity of each flip-flop belonging to one group of the pair, and configuring a scan chain of each pair,
the EDA tool being able to call the expected value derivation module, the grouping module, and the scan chain configuration module.

3. The EDA tool according to claim 1, wherein the expected value derivation module derives, by calculating probability propagation, the expected value of each flip-flop of the semiconductor device subject to verification.

4. The EDA tool according to claim 1, wherein the expected value derivation module derives, by performing logic simulation, the expected value of each flip-flop of the semiconductor device subject to verification.

5. The EDA tool according to claim 1, wherein the grouping module reads a step width of each group which is used as a basis for determination at the time of grouping, and determines which group the expected value of each flip-flop of the semiconductor device subject to verification belongs to.

6. A semiconductor device comprising:
a plurality of scan chains including a first scan chain and a second scan chain,
wherein an expected value that each flip-flop belonging to the first scan chain takes a logical value “1” falls within a first step width, an expected value that each flip-flop belonging to the second scan chain takes the logical value “1” falls within a second step width, and the first step width and the second step width differ from each other.

7. The semiconductor device according to claim 6, wherein the expected value that each flip-flop belonging to the first scan chain takes the logical value “1” and the expected value that each flip-flop belonging to the second scan chain takes the logical value “1” are obtained by probability propagation.

8. A scan chain configuration method by an EDA tool which can call an expected value derivation module, a grouping module, and a scan chain configuration module, the scan chain configuration method comprising:
an expected value derivation step of deriving, by the expected value derivation module, an expected value of each flip-flop of a semiconductor device subject to verification;
a step width readout step of reading, by the grouping module, a step width of a group;
a grouping step of determining, by the grouping module, which group corresponding to the step width each flip-flop of the semiconductor device subject to verification belongs to; and
a scan chain configuration step of configuring, by the scan chain configuration module, a scan chain with flip-flops in a group assigned in the grouping step.

9. A scan chain configuration method by an EDA tool which can call an expected value derivation module, a grouping module, and a scan chain configuration module, the scan chain configuration method comprising:
an expected value derivation step of deriving, by the expected value derivation module, an expected value of each flip-flop of a semiconductor device subject to verification;
a step width readout step of reading, by the grouping module, a step width of a group;
a grouping step of determining, by the grouping module, which group corresponding to the step width each flip-flop of the semiconductor device subject to verification belongs to;
a pair configuration step of pairing two groups among groups formed in the grouping step;
a polarity reversal step of reversing, by the scan chain configuration module, polarity of each flip-flop of one group included in a pair formed in the pair configuration step; and
a scan chain configuration step of configuring a scan chain of each pair by unifying the one group in which the polarity of each flip-flop is reversed in the polarity reversal step and the other group in which polarity of each flip-flop is not reversed.

10. The EDA tool according to claim 2, wherein the expected value derivation module derives, by calculating probability propagation, the expected value of each flip-flop of the semiconductor device subject to verification.

11. The EDA tool according to claim 2, wherein the expected value derivation module derives, by performing logic simulation, the expected value of each flip-flop of the semiconductor device subject to verification.

12. The EDA tool according to claim 2, wherein the grouping module reads a step width of each group which is used as a basis for determination at the time of grouping, and determines which group the expected value of each flip-flop of the semiconductor device subject to verification belongs to.
